(19) United States
(12) Patent Application Publication
(10) Pub. No.: US 2022/0208801 A1
(43) Pub. Date: Jun. 30, 2022

(54) ARRAY SUBSTRATE, DISPLAY PANEL, AND DISPLAY DEVICE

(71) Applicant: SHARP KABUSHIKI KAISHA, Osaka (JP)

(72) Inventor: RYOHKI ITOH, Osaka (JP)

(21) Appl. No.: 17/556,630

(22) Filed: Dec. 20, 2021

(30) Foreign Application Priority Data
Dec. 25, 2020 (JP) 2020-216992

(51) Int. Cl. H01L 27/12; H01L 27/02; G01R 31/28

(52) U.S. Cl. CPC H01L 27/1244; H01L 27/3276; G01R 31/2884; H01L 27/0292

(57) ABSTRACT

An array substrate has a display area and a non-display area, the array substrate includes: a plurality of first lines; a plurality of second lines in the display area; an inspection switching element; a plurality of third lines being connected to either a source electrode or a drain electrode; a plurality of inspection lines being connected respectively to the plurality of third lines; and a dummy line in the non-display area, wherein at least one of the plurality of inspection lines and the dummy line overlap the plurality of third lines with a first insulation film intervening therebetween in such a manner, and overlapping regions where the dummy line overlaps the plurality of third lines are closer to the outer peripheral portion of the non-display area than are overlapping regions where the plurality of inspection lines overlap the plurality of third lines.

### CROSS-REFERENCE TO RELATED APPLICATION

The present application claims priority from Japanese Application JP 2020-216992, the content to which is hereby incorporated by reference into this application.

### BACKGROUND

The technology described in the specification of the present application relates to array substrates, display panels, and display devices.

### TECHNICAL FIELD

A liquid crystal display device includes a matrix of multiple pixels in a display area of a liquid crystal panel that is a major component of the device. The alignment of liquid crystal molecules in the pixels is controlled by adjusting the individual voltages applied to the pixels, to display desired images. The image may not be properly displayed if suitable voltage is not applied to each pixel due to a manufacturing defect in the liquid crystal panel.

A known solution to this problem is to provide inspection lines and inspection switching elements outside the display area (i.e., inside the non-display area) for the purpose of performing a post-manufacture operation test on the liquid crystal panel. PCT International Application Publication No. WO2013/161661 gives such an example. The PCT International Application Publication describes data inspection lines, gate inspection lines, and inspection transistors (inspection switching elements) that are monolithically formed in the non-display area of one of two substrates (an array substrate and an active matrix substrate) in the liquid crystal panel.

### SUMMARY

In the manufacture of an array substrate, a metal film may be charged in some cases, for example, during film formation by plasma CVD (chemical vapor deposition) or during dry etching. This electric charge is known to possibly lead to ESD (electrostatic discharge). ESD can occur through various paths. Particularly of note is that the inspection lines mentioned above are likely to be affected by ESD because the inspection lines are located close to an outer peripheral portion of the non-display area of the array substrate. More specifically, if ESD occurs where a metal film constituting inspection lines intersect with another metal film with an insulation film intervening therebetween, the insulation film might be destructed, allowing an interlayer leak current between the two metal films.

The technology described in the specification of the present application has been developed in view of these issues and has an object to suppress ESD-induced interlayer leak current.

(1) The technology described in the specification of the present application is directed to an array substrate having a display area and a non-display area surrounding the display area, the array substrate including: a plurality of first lines running in parallel in a first direction in the display area; a plurality of second lines running in parallel in a second direction in the display area, the second direction intersecting with the first direction; an inspection switching element in the non-display area, the inspection switching element being connected to the plurality of first lines extended from the display area; a plurality of third lines running in the first direction in the non-display area, the plurality of third lines being connected to either a source electrode or a drain electrode of the inspection switching element; a plurality of inspection lines running in the second direction in the non-display area, the plurality of inspection lines being connected respectively to the plurality of third lines; and a dummy line running in the second direction in the non-display area, the dummy line being adjacent to an outermost inspection line that is one of the plurality of inspection lines that is located closest to an outer peripheral portion of the non-display area, wherein at least one of the plurality of inspection lines and the dummy line overlap the plurality of third lines with a first insulation film intervening therebetween in such a manner as to intersect with the plurality of third lines in a plan view, and overlapping regions where the dummy line overlaps the plurality of third lines are closer to the outer peripheral portion of the non-display area than are overlapping regions where the plurality of inspection lines overlap the plurality of third lines.

(2) In the array substrate described in (1), the dummy line may be closer to the outer peripheral portion of the non-display area than is the outermost inspection line.

(3) In the array substrate described in (1) or (2), the first insulation film may be destructed in the overlapping regions where the dummy line overlaps the plurality of third lines, so that the dummy line is short-circuited to the plurality of third lines at a short-circuiting site, and the dummy line may be partially cut such that the short-circuiting site is electrically isolated on the plurality of third lines.

(4) In the array substrate described in any one of (1) to (3), the plurality of first lines may be source lines connected to source electrodes of pixel switching elements arranged in a matrix in the display area, the plurality of second lines may be gate lines connected to gate electrodes of the pixel switching elements, and the gate lines, the plurality of inspection lines, and the dummy line may be made from a first metal film, and the source lines and the plurality of third lines may be made from a second metal film disposed in an overlying layer of the first metal film with the first insulation film intervening therebetween.

(5) In the array substrate described in any one of (1) to (3), the plurality of first lines may be gate lines connected to gate electrodes of pixel switching elements arranged in a matrix in the display area, the plurality of second lines may be source lines connected to source electrodes of the pixel switching elements, and the gate lines, the plurality of inspection lines, and the dummy line may be made from a first metal film, and the source lines and the plurality of third lines may be made from a second metal film disposed in an overlying layer of the first metal film with the first insulation film intervening therebetween.

(6) The array substrate described in any one of (1) to (3) may further include a matrix of touch electrodes in the display area, the touch electrodes being configured to form electrostatic capacitance between the touch electrodes and a position input body for use in making a position-dependent input and to detect a location of an input made using the position input body, wherein the plurality of first lines may be touch lines connected to the touch electrodes, the plurality of second lines may be gate lines connected to gate electrodes of pixel switching elements arranged in a matrix in the display area, and the gate lines, the plurality of inspection lines, and the dummy line may be made from a first metal film, the plurality of third lines may be made from a second metal film disposed in an overlying layer of the first metal film with the first insulation film intervening therebetween, and the touch lines may be made from a third metal film disposed in an overlying layer of the second metal film with a second insulation film intervening therebetween.

(7) The technology described in the specification of the present application is directed to a display panel including: the array substrate of any one of (1) to (6); an opposite substrate disposed facing the array substrate in such a manner as to have an internal space between the opposite substrate and the array substrate; and a medium layer of functional organic molecules in the internal space.

(8) The technology described in the specification of the present application is directed to a display panel including: the array substrate of any one of (1) to (6); light-emitting elements on the array substrate; and a sealing layer disposed so as to cover the light-emitting elements.

(9) The technology described in the specification of the present application is directed to a display device including the display panel of (7) or (8).

The technology described in the specification of the present application is capable of suppressing ESD-induced interlayer leak current.

### BRIEF DESCRIPTION OF DRAWINGS

FIG. 1 is a plan view of a liquid crystal display device in accordance with Embodiment 1.

FIG. 2 is a schematic cross-sectional view of a thickness-wise structure of a liquid crystal panel.

FIG. 3 is a circuit diagram of a display area of an array substrate.

FIG. 4 is an enlarged diagram of an enclosed region IV that is indicated in FIG. 1.

FIG. 5 is an enlarged diagram of an enclosed region V that is indicated in FIG. 1.

FIG. 6 is a plan view of a wiring pattern on an array substrate shown in FIG. 4.

FIG. 7 is a plan view of a wiring pattern on an array substrate shown in FIG. 5.

FIG. 8 is a cross-sectional view taken along line A-A that is indicated in FIG. 6.

FIG. 9 is a cross-sectional view of a dummy line forming an interlayer connection with, and hence being short-circuited to, a source-inspection-TFT pull-out line.

FIG. 10 is a plan view of a liquid crystal display device in accordance with Embodiment 2.

FIG. 11 is an enlarged view of an enclosed region XI that is indicated in FIG. 10 with a source driver being removed.

FIG. 12 is a plan view of a wiring pattern on an array substrate shown in FIG. 11.

FIG. 13 is a plan view of a liquid crystal display device in accordance with Embodiment 3.

FIG. 14 is an enlarged view of an enclosed region XIV that is indicated in FIG. 13.

FIG. 15 is a plan view of a wiring pattern on an array substrate shown in FIG. 14.

FIG. 16 is a cross-sectional view taken along line B-B that is indicated in FIG. 15.

FIG. 17 is a cross-sectional view taken along line C-C that is indicated in FIG. 15.

FIG. 18 is a schematic exploded perspective view of a structure of an OLED panel.

### DESCRIPTION OF EMBODIMENTS

### Embodiment 1

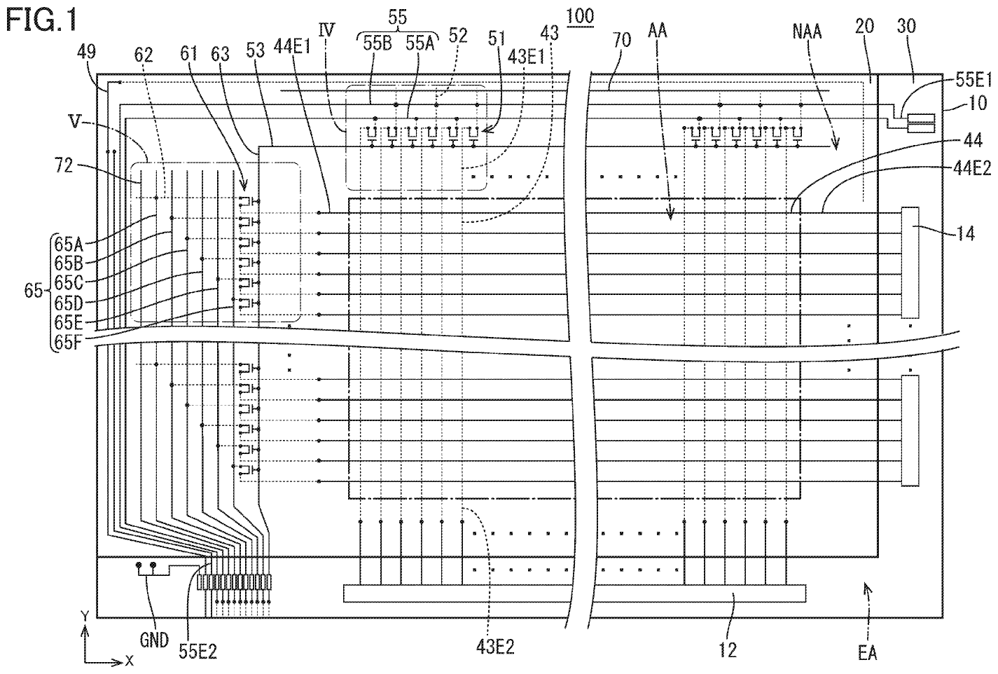

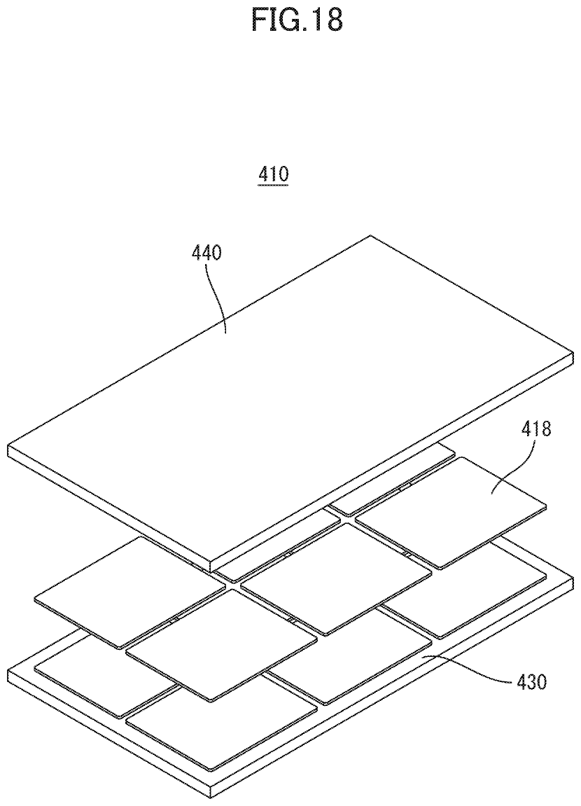

The following will describe Embodiment 1 of the present invention with reference to FIGS. 1 to 9. The present embodiment takes as an example a liquid crystal display device 100 (an example of the display device) including a liquid crystal panel 10 (an example of the display panel). However, the present invention is also applicable to display devices including other types of display panels (e.g., an OLED panel 410 shown in FIG. 18). Some of the drawings show an X-axis, a Y-axis, and/or a Z-axis whose directions are designated commonly for all the drawings. All the cross-sectional views are drawn so that the front side (display surface side) of the liquid crystal panel 10 faces upwards and the back side (rear side, opposite the display surface) thereof faces downwards.

Referring to FIG. 1, the liquid crystal display device 100 includes: the liquid crystal panel 10 capable of displaying images; a source driver 12 for driving the liquid crystal panel 10; and gate drivers 14. The liquid crystal panel 10 is rectangular and landscape oriented and has a face divided into a centrally located display area (active area) AA capable of displaying images and a frame-shaped non-display area (non-active area) NAA surrounding the display area AA in a plan view. In FIG. 1, the perimeter of the display area AA is indicated by a dash-dot line, and the non-display area NAA lies outside the dash-dot line.

The source driver 12 and the gate drivers 14 are LSI chips including a source drive circuit and a gate drive circuit respectively. These drivers 12 and 14 are connected via a flexible substrate to a control board that is a source of supply of various signals. The liquid crystal display device 100 further includes a backlight device on the back of the liquid crystal panel 10. The backlight device emits light to produce a display on the liquid crystal panel 10.

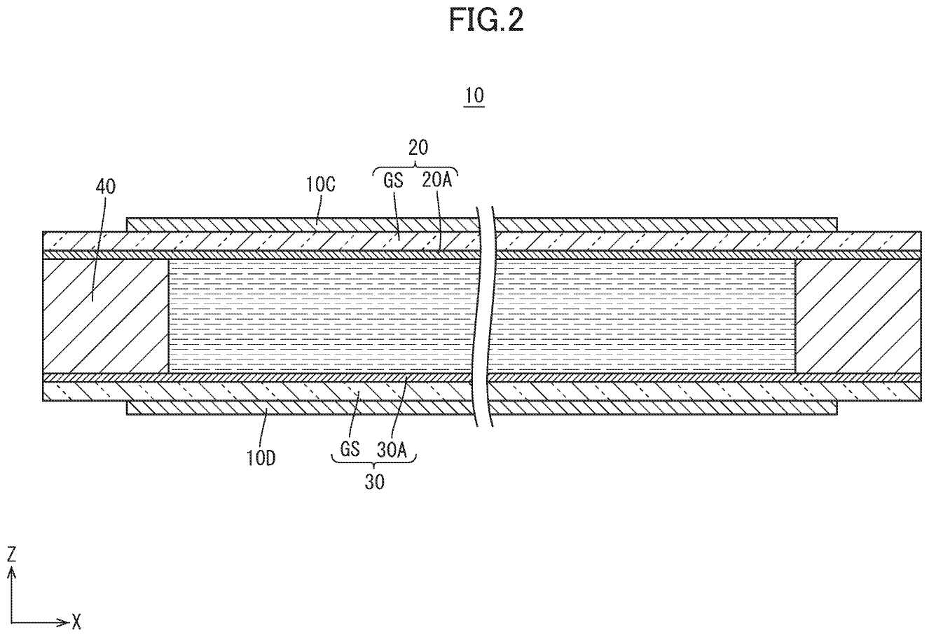

Referring to FIG. 2, the liquid crystal panel 10 includes a pair of substrates 20 and 30, a liquid crystal layer 18, and a sealing section 40. The liquid crystal layer 18 is a medium layer interposed in the internal space between the substrates 20 and 30 and containing liquid crystal molecules (an example of functional organic molecules) that change the optical properties thereof under an electric field. The sealing section 40 is provided around the liquid crystal layer 18 between the substrates 20 and 30 to seal the liquid crystal layer 18 and combine the substrates 20 and 30 together. Of the two substrates 20 and 30, the one on the front side is the CF substrate (color filter substrate, opposite substrate) 20, and the one on the back side is the array substrate (active matrix substrate, TFT substrate) 30. The CF substrate 20 and the array substrate 30 are glass substrates GS (an example of an insulating substrate) carrying stacks of various patterned thin films 20A and 30A respectively on the inner faces thereof. The liquid crystal panel 10 is manufactured by combining the substrates 20 and 30 together using the sealing section 40 in such a manner that the thin films 20A and 30A face each other, encapsulating the liquid crystal layer 18, and then attaching polarizers 10C and 10D on the outer faces of the substrates 20 and 30 respectively.

Referring to FIG. 1, the array substrate 30 has somewhat larger dimensions than the CF substrate 20 in a plan view and has a face divided into the display area AA and the non-display area NAA. The array substrate 30 is combined with the CF substrate 20 by the sealing section 40 with one of the longer sides and one of the shorter sides of the array substrate 30 being aligned with the corresponding one of the longer sides and the corresponding one of the shorter sides of the CF substrate 20 respectively, so that the array substrate 30 has an area EA where the array substrate 30 does not overlap the CF substrate 20 and is hence exposed. The exposed area EA is a part of the non-display area NAA. The source driver 12 is mounted by COG (chip-on-glass) to the portion of the exposed area EA that is shown on the bottom of FIG. 1. The gate drivers 14 are mounted by COG to the portion of the exposed area EA that is shown in the right side of FIG. 1, so as to be positioned next to each other with an intervening distance therebetween.

The array substrate 30 includes, in the display area AA thereof, a lattice of multiple source lines (data lines, signal lines) 43 running in the Y-axis direction and multiple gate lines (scan lines) 44 running in the X-axis direction that is perpendicular to the source lines 43, as shown in FIG. 1. When the source lines 43 are first lines, the gate lines 44 are second lines.

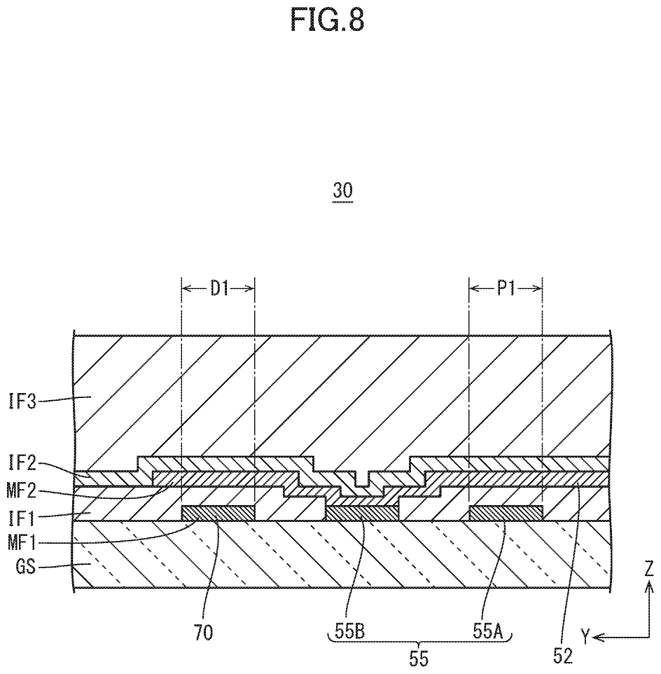

Conversely, when the gate lines 44 are first lines, the source lines 43 are second lines. In the display area AA, the gate lines 44 are fabricated from a gate metal film MF1 (an example of the first metal film), and the source lines 43 are fabricated from a source metal film MF2 (an example of the second metal film), as will be described later in detail. The source metal film MF2 is located above the gate metal film MF1 with a gate insulation film IF1 (an example of the first insulation film) being interposed therebetween (see FIG. 8). FIG. 1 indicates wiring fabricated from the gate metal film MF1 using solid lines and wiring fabricated from the source metal film MF2 using dotted lines. FIG. 1 also indicates the locations of interlayer connections between different sets of wiring using black circles. At those intersections of the solid and dotted lines that are not marked with black circles, the sets of wiring form no interlayer connections and are stacked (one set overlapping the other when viewed normal to the array substrate 30) with the gate insulation film IF1 being interposed therebetween.

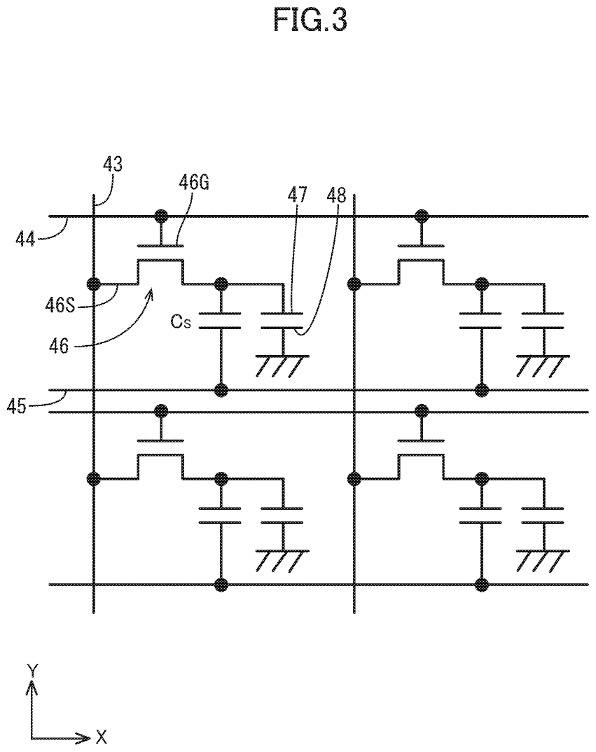

There are provided a pixel switching element (more particularly, a pixel TFT 46 (thin film transistor)) and a pixel electrode 47 in each region surrounded by the source lines 43 and the gate lines 44, as shown in FIG. 3. The pixel TFTs 46 and the pixel electrodes 47 are provided in large numbers in a matrix form in the display area AA. There is also provided a common electrode 48 in the display area AA of the array substrate 30. A reference electrical potential is fed to the common electrode 48.

Referring to FIG. 1, the source lines 43 are extended generally straightly in the Y-axis direction so as to have upper and lower end portions 43E1 and 43E2 thereof stretching from the display area AA into the non-display area NAA. The lower end portion 43E2 of each source line 43 is connected to the source driver 12, so that the source line 43 is fed with a data signal (image signal) from a source drive circuit in the source driver 12. Meanwhile, the gate lines 44 are extended generally straightly in the X-axis direction so as to have left and right end portions 44E1 and 44E2 thereof stretching from the display area AA into the non-display area NAA. The right end portion 44E2 of each gate line 44 is connected to one of the gate drivers 14, so that the gate line 44 is fed with a gate signal (scan signal) from a gate drive circuit in the gate driver 14.

When the pixel TFT 46 is fed with a gate signal via the gate line 44 and a data signal via the source line 43, the pixel electrode 47 connected to the pixel TFT 46 is charged, changing the electrical potential difference between the pixel electrode 47 and the common electrode 48. This electrical potential difference controls the electric field applied to the liquid crystal layer 18, thereby switching the alignment of the liquid crystal molecules in a suitable manner to drive the liquid crystal panel 10. The liquid crystal panel 10 in accordance with the present embodiment operates in FFS (fringe field switching) mode where a so-called fringe field switches the liquid crystal molecules. The liquid crystal panel 10 may alternatively operate in a non-FFS mode of operation including, e.g., IPS (in-plane-switching) mode, VA (vertical alignment) mode, and TN (twisted nematic) mode.

There are also provided auxiliary capacitor lines 45 and auxiliary capacitors Cs in the display area AA of the array substrate 30, as shown in FIG. 3, to retain an electrical potential on the charged pixel electrodes 47. The auxiliary capacitor lines 45 run parallel to the gate lines 44 and are fed with a reference electrical potential. There is also provided a common electrode wire 49 in the non-display area NAA of the array substrate 30 to supply the reference electrical potential to the common electrode 48 as shown in FIG. 1. FIG. 1 omits the auxiliary capacitor lines 45 to distinctly show other wiring.

The various thin films 20A on the CF substrate 20 have multiple color filters formed thereon opposite the pixel electrodes 47 on the array substrate 30. The color filters include colored films that give off red, green, and blue (R, G and B) colors such that the color filters can selectively transmit light that has a particular range of wavelengths corresponding to these color. The colored films are arranged in such a manner that the colors repeatedly appear in a prescribed sequence when traced along the Y-axis direction.

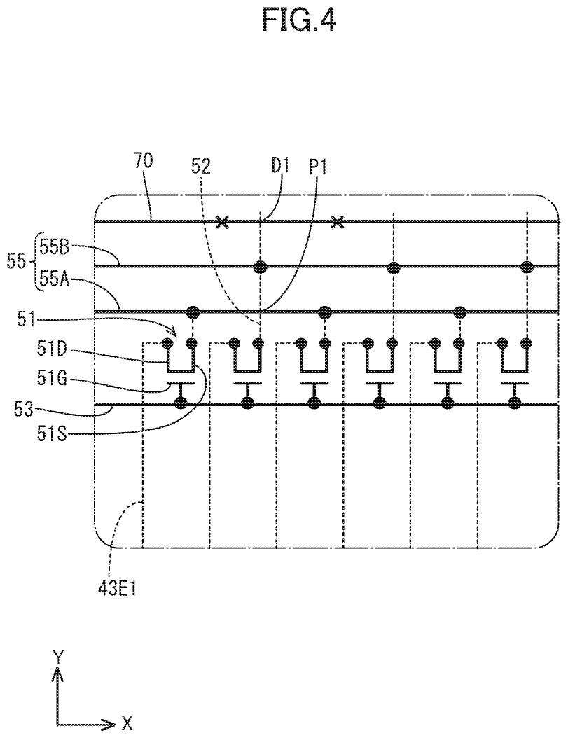

After the stack of the various thin films 30A is formed, an external inspection instrument is connected to the array substrate 30 to subject the array substrate 30 to an operation test. In the operation test, inspection signals are fed from the inspection instrument to the array substrate 30 to verify the operating condition of the array substrate 30. To this end, the array substrate 30 includes source inspection lines 55, source-inspection switching elements (source inspection TFTs) 51, a source-inspection-TFT control line 53, and source-inspection-TFT pull-out lines 52, as shown in FIGS. 1 and 4, to feed inspection data signals (data inspection signals) to the source lines 43. The array substrate 30 further includes gate inspection lines 65, gate inspection switching elements (gate inspection TFTs) 61, a gate-inspection-TFT control line 63, and gate-inspection-TFT pull-out lines 62, to feed inspection gate signals (gate inspection signals) to the gate lines 44. The inspection TFTs 51 and 61, the inspection lines 55 and 65, the inspection-TFT control lines 53 and 63, and the inspection-TFT pull-out lines 52 and 62 are used to perform an operation test on the array substrate 30, not to actually drive the liquid crystal panel 10.

The source inspection lines 55 are fed with a data inspection signal from the external inspection instrument. The gate inspection lines 65 are fed with a gate inspection signal from the external inspection instrument. The source inspection TFT 51 controls the feeding of the data inspection signal from the source inspection lines 55 to the source lines 43. The gate inspection TFT 61 controls the feeding of the gate inspection signal from the gate inspection lines 65 to the gate lines 44. The source-inspection-TFT control line 53 is fed with a switching signal for switching the driving of the source inspection TFT 51. The gate-inspection-TFT control line 63 is fed with a switching signal for switching the driving of the gate inspection TFT 61. The inspection TFTs 51 and 61 (inspection switching elements) may be referred to as ASL-SWs or ASL-TFTs because the operation test is performed using ASL inspection techniques.

The source inspection TFTs 51 are provided in the non-display area NAA opposite from the source driver 12 as shown in FIG. 1 (on the top of FIG. 1). There is provided one source inspection TFT 51 for each source line 43. The source inspection TFTs 51 are arranged next to each other along the X-axis. The source inspection TFTs 51 have drain electrodes 51D thereof connected to the upper end portions 43E1 (end portions opposite the end portions 43E2 connected to the source driver 12) of the source lines 43 respectively as shown in FIG. 4. The source inspection TFTs 51 have source electrodes 51S thereof connected to the source inspection lines 55 via the source-inspection-TFT pull-out lines 52 (an example of third lines) running in the Y-axis direction respectively. The source inspection TFTs 51 have gate electrodes 51G thereof connected to the source-inspection-TFT control line 53.

The source inspection lines 55 run overall like a letter L in the non-display area NAA as shown in FIG. 1. One of the two end portions of each source inspection line 55 (end portion 55E1) extends into the exposed area EA in the right side, and the other end portion 55E2 extends into the exposed area EA on the bottom. At least two (two in the present embodiment) source inspection lines 55 are provided parallel to each other as shown in FIGS. 1 and 4. One of the two source inspection lines 55 that is closer to the display area AA (source inspection line 55A) is connected via the source-inspection-TFT pull-out lines 52 to those source inspection TFTs 51 that are odd-numbered (first, third, fifth . . . ) when counted from the right side of FIG. 1. Meanwhile, one of the two source inspection lines 55 that is closer to the outer peripheral portion of the non-display area NAA (source inspection line 55B (an example of outermost inspection line)) is connected via the source-inspection-TFT pull-out lines 52 to those source inspection TFTs 51 that are even-numbered (second, fourth, sixth . . . ) when counted from the right side of FIG. 1. The source-inspection-TFT pull-out lines 52 are pulled out in the Y-axis direction so as to connect the source inspection lines 55 to the source electrodes 51S of the source inspection TFTs 51 as shown in FIG. 4.

The source-inspection-TFT control line 53 is extended generally straightly in the X-axis direction from the respective source inspection lines 55 toward the display area AA as shown in FIG. 1. One of the ends of the source-inspection-TFT control line 53 (the left end) is connected to the gate-inspection-TFT control line 63 (detailed later). The inspection-TFT control lines 53 and 63 are integrally formed as a single L-shaped wire. The source-inspection-TFT control line 53 is connected to the gate electrodes 51G of the source inspection TFTs 51 as shown in FIG. 4.

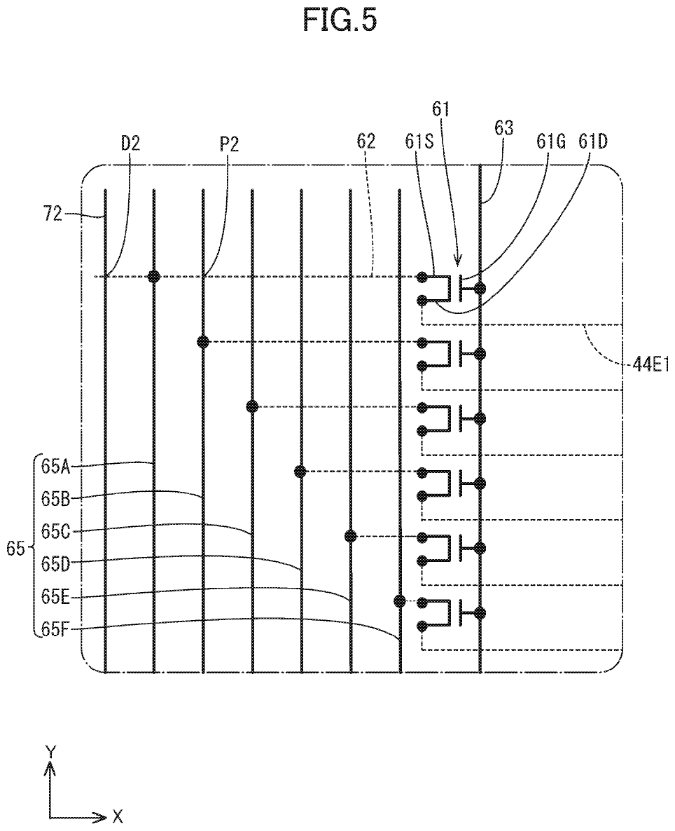

The gate inspection TFTs 61 are provided in the non-display area NAA opposite from the gate drivers 14 as shown in FIG. 1 (in the left side of FIG. 3). There is provided one gate inspection TFT 61 for each gate line 44. The gate inspection TFT 61 are arranged next to each other along the Y-axis direction. The gate inspection TFTs 61 have drain electrodes 61D thereof connected to the left end portion 44E1 (end portions opposite the end portions 44E2 connected to the gate drivers 14) of the gate lines 44 respectively as shown in FIG. 4. The gate inspection TFTs 61 have source electrodes 61S thereof connected to the gate inspection lines 65 via the gate-inspection-TFT pull-out lines 62 (another example of the third lines) running in the X-axis direction. The gate-inspection-TFT pull-out lines 62 are pulled out in the X-axis direction so as to connect the gate inspection lines 65 to the source electrodes 61S of the gate inspection TFTs 61 as shown in FIG. 5. The gate inspection TFTs 61 have gate electrodes 61G thereof connected to the gate-inspection-TFT control line 63. The gate-inspection-TFT control line 63 is extended generally straightly in the Y-axis direction from the left end of the source-inspection-TFT control line 53 as shown in FIG. 1 and formed integrally to the source-inspection-TFT control line 53.

The gate inspection lines 65 are extended generally straightly in the Y-axis direction from the gate-inspection-TFT control line 63 toward the outer peripheral portions as shown in FIG. 1. At least two (six in the present embodiment) gate inspection lines 65 are provided parallel to each other. One of the gate inspection lines 65 that is the closest to the outer peripheral portion of the non-display area NAA (gate inspection line 65A, which is the first gate inspection line 65 when counted along the X-axis direction from the left side of FIG. 1) (another example of outermost inspection line) is connected via the gate-inspection-TFT pull-out lines 62 to those gate inspection TFTs 61 that are the first, seventh, and thirteenth . . . when counted from the top of FIG. 1. Meanwhile, one of the gate inspection lines 65 that is immediately right to the gate inspection line 65A (gate inspection line 65B, which is the second gate inspection line 65 when counted along the X-axis direction from the left side of FIG. 1) is connected via the gate-inspection-TFT pull-out lines 62 to those gate inspection TFTs 61 that are the second, eighth, fourteenth . . . when counted from the top of FIG. 1. Likewise, those gate inspection lines 65 that are the third, fourth, fifth, and sixth when counted along the X-axis direction from the left side (gate inspection lines 65C, 65D, 65E, and 65F) are connected respectively to the gate inspection TFTs 61 via the gate-inspection-TFT pull-out lines 62.

In accordance with the present embodiment, the array substrate 30 further includes a dummy line 70 as an ESD countermeasure that may occur on the source inspection lines 55 and a dummy line 72 as an ESD countermeasure that may occur on the gate inspection lines 65, as shown in FIGS. 1 and 4 to 7. The dummy line 70 is extended generally straightly in the X-axis direction and located adjacent to the source inspection line 55B, which is one of the two source inspection lines 55 that is the closest to the outer peripheral portion of the non-display area NAA. The dummy line 70 is disposed closer to the outer peripheral portion of the non-display area NAA than the source inspection line 55B is close to the outer peripheral portion of the non-display area NAA. In other words, the dummy line 70 is disposed closer to the outer peripheral portion of the non-display area NAA than all the source inspection lines 55 are close to the outer peripheral portion of the non-display area NAA. The source-inspection-TFT pull-out lines 52, connected to the source inspection line 55B, extend toward the outer peripheral portion of the non-display area NAA and intersect with the dummy line 70. The source-inspection-TFT pull-out lines 52 overlap the dummy line 70 with the gate insulation film IF1 being interposed therebetween (FIG. 8). The dummy line 72 is extended generally straightly in the Y-axis direction and located adjacent to the gate inspection line 65A, which is one of the six gate inspection lines 65 that is the closest to the outer peripheral portion of the non-display area NAA. The dummy line 72 is disposed closer to the outer peripheral portion of the non-display area NAA than the gate inspection line 65A is close to the outer peripheral portion of the non-display area NAA. In other words, the dummy line 72 is disposed closer to the outer peripheral portion of the non-display area NAA than all the gate inspection lines 65 are close to the outer peripheral portion of the non-display area NAA. The gate-inspection-TFT pull-out lines 62, connected to the gate inspection line 65A, extend toward the outer peripheral portion of the non-display area NAA and intersect with the dummy line 72. The gate-inspection-TFT pull-out lines 62 overlap the dummy line 72 with the gate insulation film IF1 being interposed therebetween.

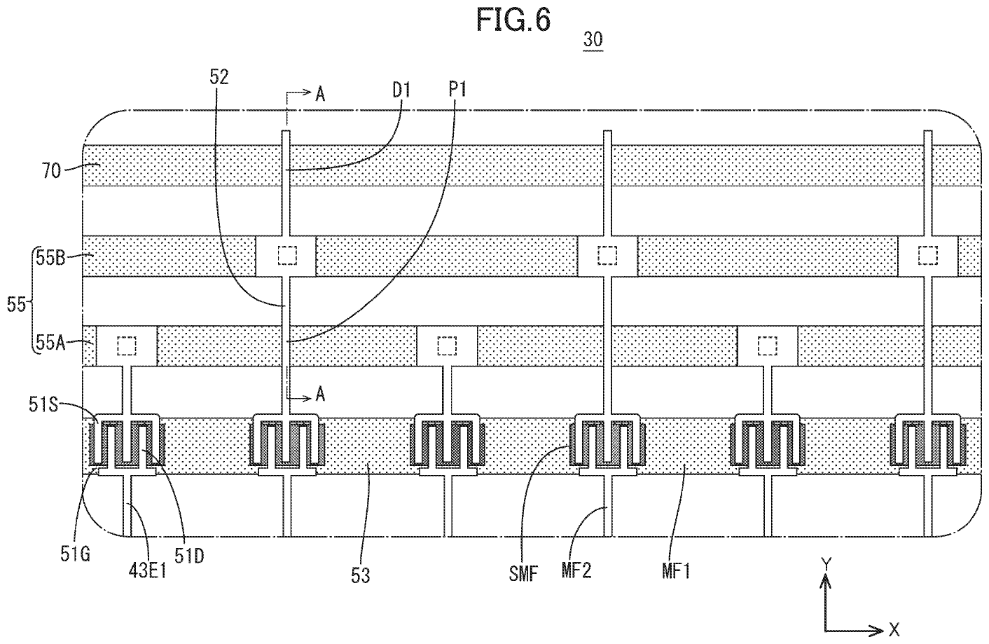

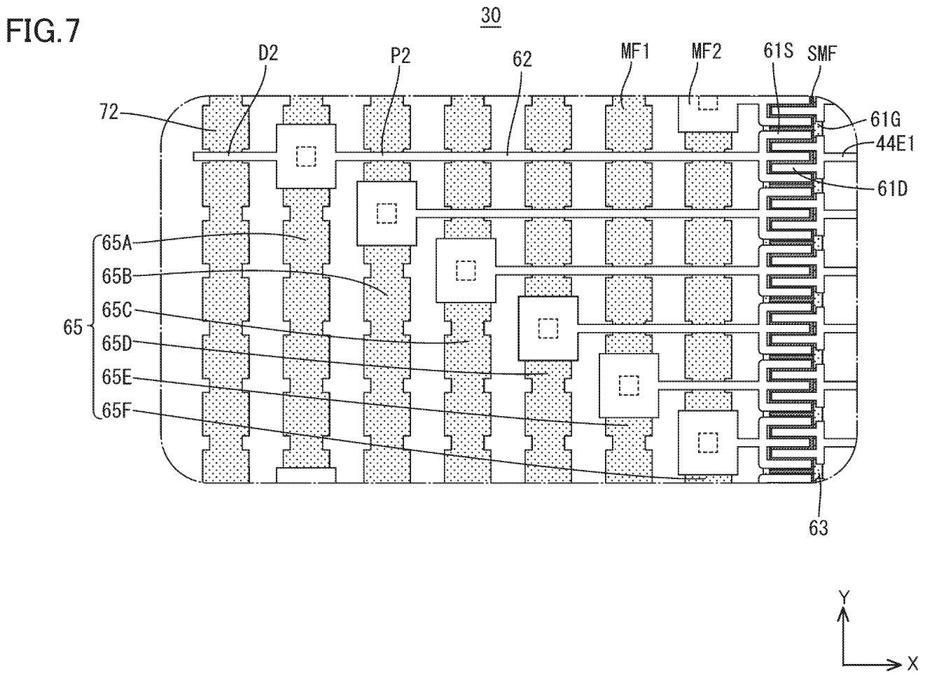

The various thin films 30A on the array substrate 30 (including the source lines 43, the gate lines 44, the auxiliary capacitor lines 45, the pixel TFTs 46, the pixel electrodes 47, the common electrode 48, the common electrode wire 49, the inspection TFTs 51 and 61, the inspection-TFT pull-out lines 52 and 62, the inspection-TFT control lines 53 and 63, the inspection lines 55 and 65, and the dummy lines 70 and 72) are formed by stacking various patterned films by a known photolithography technique. Specifically, the gate lines 44, gate electrodes 46G of the pixel TFTs 46, the gate electrodes 51G and 61G of the inspection TFTs 51 and 61, the inspection-TFT control lines 53 and 63, the inspection lines 55 and 65, and the dummy lines 70 and 72 are formed by patterning the gate metal film MF1 stacked on the glass substrate GS, as indicated by thin hatching in FIGS. 6 and 7. The dummy lines 70 and 72 are formed to have the same shape and width as those portions adjacent to the inspection lines 55B and 65A as shown in FIG. 7. The source lines 43, the auxiliary capacitor lines 45, source electrodes 46S and drain electrodes 46D of the pixel TFTs 46, the source electrodes 51S and 61S and the drain electrodes 51D and 61D of the inspection TFTs 51 and 61, and the inspection-TFT pull-out lines 52 and 62 are formed by patterning the source metal film MF2 stacked on an overlying side of the gate metal film MF1 with the gate insulation film IF1 being interposed therebetween. The pixel TFTs 46 and the inspection TFTs 51 and 61 are bottom-gate TFTs. A semiconductor film SMF, which will be channel regions for the TFTs, is stacked between and the gate insulation film IF1 and the source metal film MF2 in the area where these TFTs are provided. A first interlayer insulation film (passivation film, inorganic insulation film) IF2 and a planarization film (passivation film, organic insulation film) IF3 are stacked on the source metal film MF2 as shown in FIG. 8. The pixel electrodes 47 are formed from a first transparent electrode film stacked on the planarization film IF3. The common electrode 48 is formed of a second transparent electrode film stacked on an overlying side of the first transparent electrode film with a second interlayer insulation film IF4 being interposed therebetween.

The gate metal film MF1 and the source metal film MF2 are made of either a monolayer film of a metal such as copper (Cu) or of an alloy or a stack of these films, so that every wire and electrode made from the metal films MF1 and MF2 is electrically conductive and opaque to light. The gate metal film MF1 and the source metal film MF2 may be made of the same material or different materials. In the present embodiment, the gate metal film MF1 and the source metal film MF2 are made of a stack of copper (Cu) and titanium (Ti) films and have a thickness of, for example, 0.1 μm to 0.3 μm. The gate insulation film IF1 is made of a transparent, inorganic insulating material that is either a monolayer of, for example, silicon oxide (SiOx), silicon oxynitride (SiON), or silicon nitride (SiNx) or a stack of these layers. The gate insulation film IF1, in the present embodiment, is made of silicon nitride (SiNx) or silicon oxide (SiO₂) and has a thickness of, for example, 0.2 μm to 0.6 μm. The first and second interlayer insulation films IF2 and IF4 are made of an inorganic insulating material such as silicon nitride (SiNx) or silicon oxide (SiO₂) and have a thickness of, for example, approximately 0.2 μm. The planarization film IF3 is made of a transparent, organic insulating material such as an acrylic resin (e.g., PMMA) or a polyimide resin and has a thickness of, for example, approximately 2.0 μm, which is larger than the thicknesses of the other insulation films. The semiconductor film SMF is made of, for example, a thin film of, for example, an oxide semiconductor or amorphous silicon. The first and second transparent electrode films are made of a transparent electrode material, for example, ITO (indium tin oxide) or IZO (indium zinc oxide).

A metal film might be charged, which can lead to ESD, for example, during film formation by plasma CVD or during dry etching in photolithography-based manufacturing. ESD can occur through various paths. The source inspection lines 55 and the gate inspection lines 65 described above are located close to the outer peripheral portion of the non-display area NAA and therefore likely to provide paths for ESD occurrences. Particularly, if ESD occurs where the inspection lines 55 and 65 fabricated from the gate metal film MF1 intersect with (overlap) the inspection-TFT pull-out lines 52 and 62 fabricated from the source metal film MF2 with the gate insulation film IF1 interposed therebetween, the gate insulation film IF1 is likely to be destructed, possibly causing interlayer leak current between the two metal films MF1 and MF2. This interlayer leak current can short-circuit the inspection lines 55 and 65 to the inspection-TFT pull-out lines 52 and 62, which will create difficulty in performing a normal operation test on the array substrate 30.

More particularly, for example, the source inspection line 55A intersects with the source-inspection-TFT pull-out lines 52 at intersecting sites P1 (FIG. 4). If there was provided no dummy line 70, the intersecting sites P1 would be, of all the sites where the gate metal film MF1 intersects with (overlaps) the source metal film MF2, positioned closest to the outer peripheral portion of the top of the non-display area NAA in FIG. 1 (closest to the top of FIG. 1). The gate inspection line 65B intersects with the gate-inspection-TFT pull-out lines 62 at intersecting sites P2 (FIG. 5). If there was provided no dummy line 72, the intersecting sites P2 would be, of all the sites where the gate metal film MF1 intersects (overlaps) with the source metal film MF2, positioned closest to the outer peripheral portion of the left side of the non-display area NAA in FIG. 1 (closest to the leftmost part of FIG. 1). The overlapping sites P1 and P2 shown in FIGS. 4 and 5 can therefore be ESD-prone sites that are likely to provide paths for ESD on the array substrate 30 and cause ESD-induced interlayer leak current.

Accordingly, in the present embodiment, by providing the dummy lines 70 and 72 so as to intersect with (overlap) the inspection-TFT pull-out lines 52 and 62 as described above, sites D1 and D2 where the gate metal film MF1 intersects with (overlaps) the source metal film MF2 are formed closer to the outer peripheral portion of the non-display area NAA than the ESD-prone sites P1 and P2 are close to the outer peripheral portion of the non-display area NAA. In other words, the overlapping sites (regions) D1 on the dummy line 70 and the source-inspection-TFT pull-out lines 52 are closer to the outer peripheral portion of the non-display area NAA than the overlapping sites (ESD-prone sites) P1 on the inspection lines 55 and the source-inspection-TFT pull-out lines 52 are close to the outer peripheral portion of the non-display area NAA as shown in FIGS. 4, 6, and 8. The overlapping sites (regions) D2 on the dummy line 72 and the gate-inspection-TFT pull-out lines 62 are closer to the outer peripheral portion of the non-display area NAA than the overlapping sites (ESD-prone sites) P2 on the inspection lines 65 and the gate-inspection-TFT pull-out lines 62 are close to the outer peripheral portion of the non-display area NAA as shown in FIGS. 5 and 7. This particular structure restrains ESD from being induced at the overlapping sites D1 and D2 and occurring at the ESD-prone sites P1 and P2. In other words, the overlapping sites D1 and D2 on the dummy lines 70 and 72 and the inspection-TFT pull-out lines 52 and 62 behave like ESD-inducing sites similarly to a lightning rod and restrain an ESD-induced leak current from occurring at the ESD-prone sites P1 and P2.

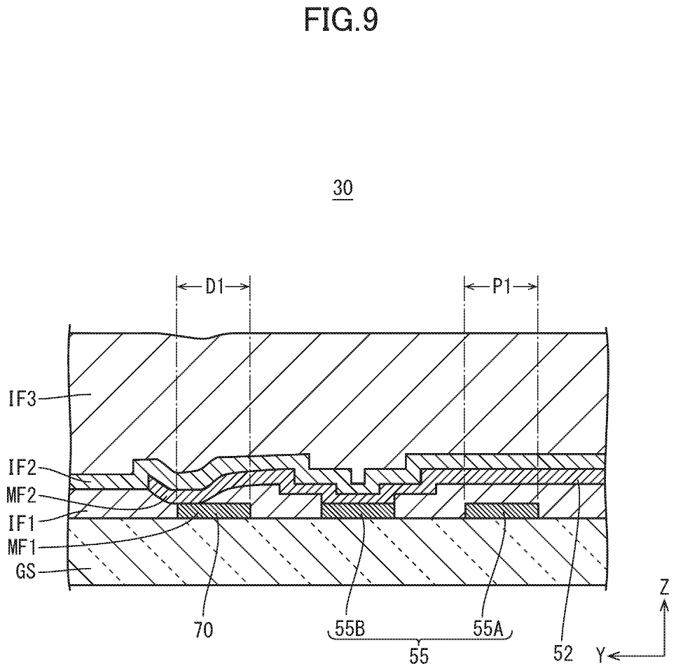

When the overlapping sites D1 and D2 on the dummy lines 70 and 72 and the inspection-TFT pull-out lines 52 and 62 behave like a lightning rod, the gate insulation film IF1 is destructed at the overlapping sites D1 and D2 by ESD, which forms interlayer connections between (hence short-circuiting) the dummy lines 70 and 72 and the inspection-TFT pull-out lines 52 and 62, as in the example shown in FIG. 9. It is possible to identify these short-circuiting sites by performing an operation test on the array substrate 30. Therefore, when this is the case, the dummy lines 70 and 72 are preferably cut at some sites under laser irradiation to electrically isolate the short-circuiting sites on the dummy lines 70 and 72 and the inspection-TFT pull-out lines 52 and 62. Specifically, the dummy line 70 is cut at sites located across the short-circuiting sites on the dummy line 70 and the source-inspection-TFT pull-out lines 52 as indicated by “x” marks in the example shown FIG. 4. This particular structure electrically isolates the short-circuiting sites, thereby enabling an operation test to be performed on the array substrate 30 in a normal fashion, even when the dummy lines 70 and 72 are short-circuited to the inspection-TFT pull-out lines 52 and 62.

To cause the overlapping regions D1 and D2 on the dummy lines 70 and 72 and the inspection-TFT pull-out lines 52 and 62 to behave like a lightning rod, theoretically, the dummy line 70 may be provided adjacent to the display area AA side of the source inspection line 55B (i.e., between the source inspection lines 55A and 55B), and the dummy line 72 may be provided adjacent to the display area AA side of the gate inspection line 65A (i.e., between the gate inspection lines 65A and 65B). In contrast, in accordance with the present embodiment, the dummy lines 70 and 72 are provided closer to the outer peripheral portion of the non-display area NAA than the source inspection line 55B and the gate inspection line 65A are close to the outer peripheral portion of the non-display area NAA respectively. This structure of the present embodiment is advantageous in that when the dummy lines 70 and 72 are cut under laser irradiation, other wiring is less likely to be adversely affected by the laser (e.g., pieces of the dummy lines 70 and 72 are less likely to be scattered over other wiring under laser irradiation).

The dummy lines 70 and 72 may be cut after an operation test is performed on the liquid crystal panel 10 with the array substrate 30 and the CF substrate 20 being combined together. In such a case, however, laser irradiation may affect the CF substrate 20 (e.g., a light-blocking film may be damaged that is provided on the CF substrate 20 to block the light coming from the backlight device). In contrast, cutting the dummy lines 70 and 72 on the array substrate 30 before the array substrate 30 is combined with the CF substrate 20 as in the present embodiment can restrain the CF substrate 20 from being adversely affected by laser irradiation.

### Embodiment 2

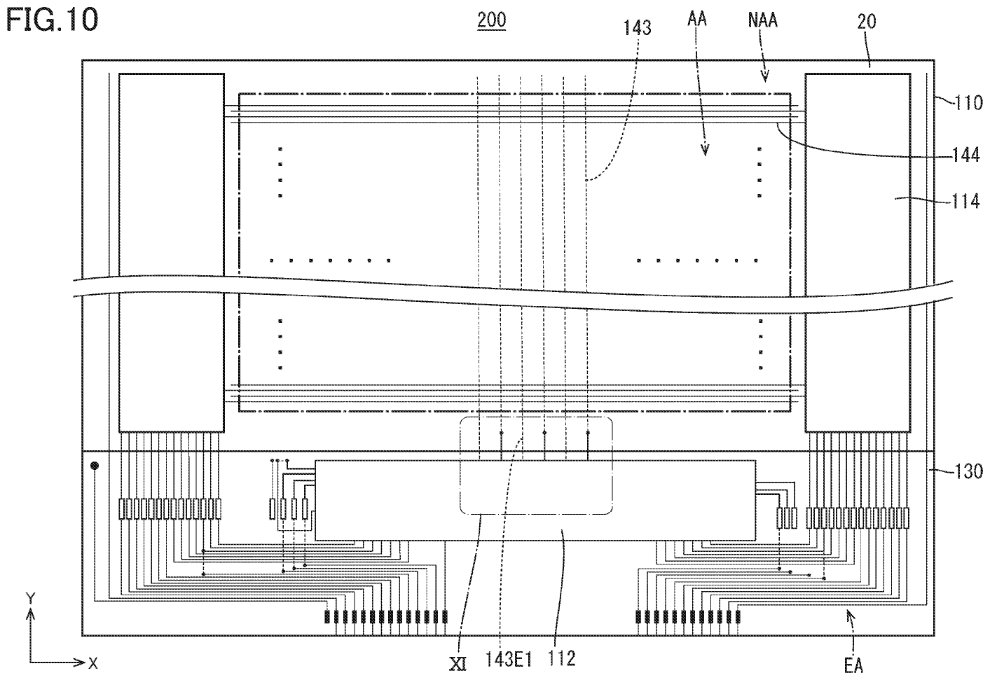

The following will describe a liquid crystal display device 200 in accordance with Embodiment 2 with reference to FIGS. 10 to 12. Duplicate description is omitted of the structures, operations, effects, and advantages of Embodiment 2 that are similar to those of Embodiment 1.

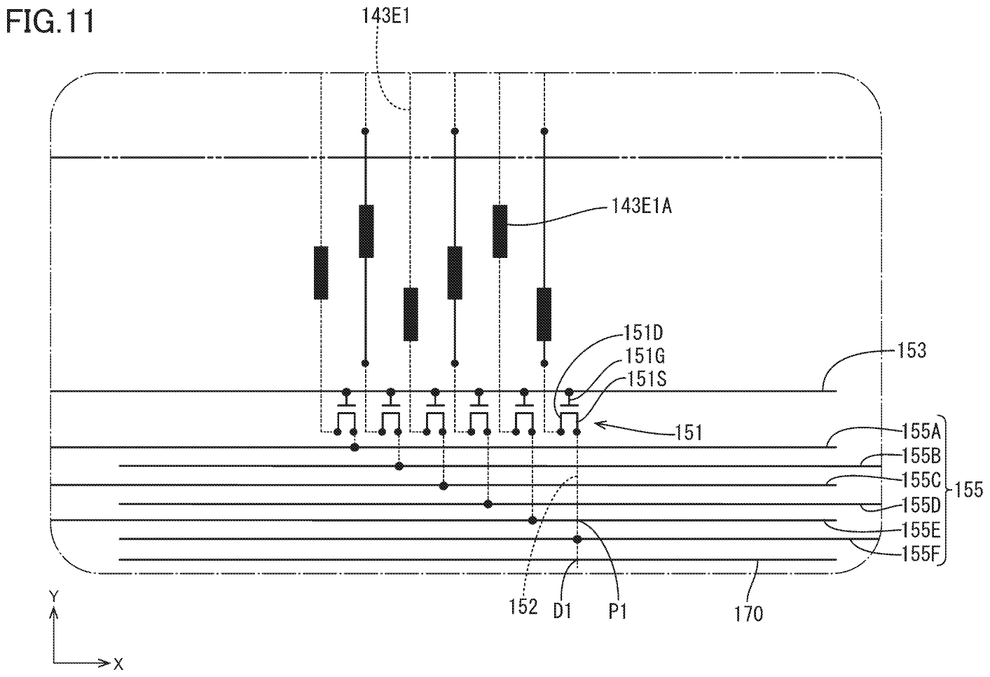

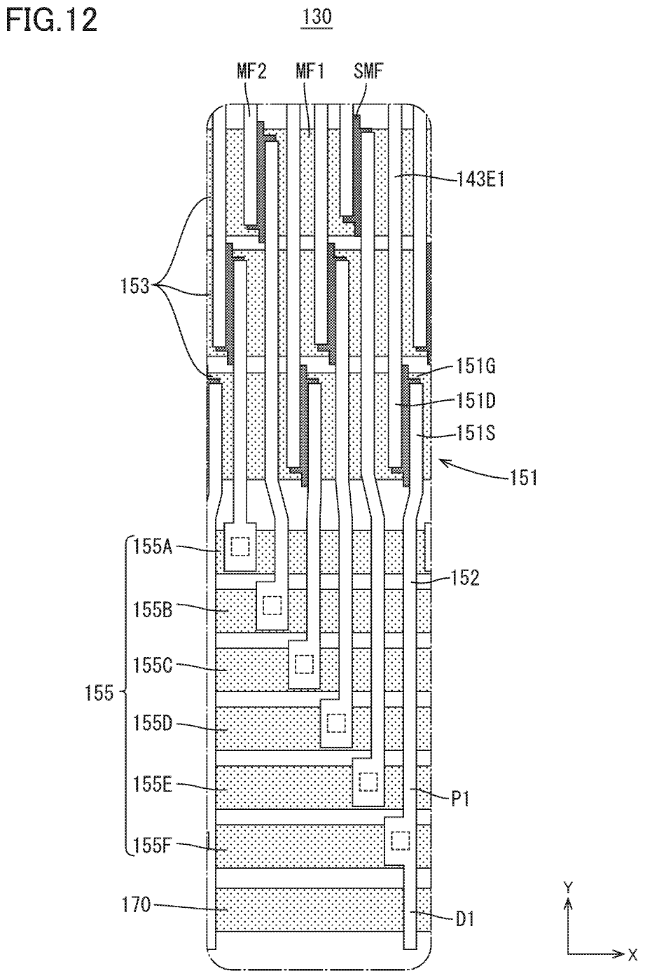

Wiring and TFTs for supplying data inspection signals to source lines 143 are provided within an area for mounting a source driver 112 in a non-display area NAA of an array substrate 130 of a liquid crystal panel 110 in accordance with the present embodiment. More particularly, there are provided source inspection lines 155, source inspection TFTs 151, a source-inspection-TFT control line 153, source-inspection pull-out lines 152, and a dummy line 170 in the non-display area NAA where the source driver 112 is mounted, as shown in FIGS. 11 and 12. This particular structure reduces the area of the non-display area NAA.

There are also provided monolithic GDM (gate driver monolithic circuit, gate drive circuit) units 114 in the non-display area NAA of the array substrate 130 as shown in FIG. 10. One of the GDM units 114 is located in the non-display area NAA in the left side of FIG. 10, and the other GDM unit 114 is located in the non-display area NAA in the right side of FIG. 10. Gate lines 144 are connected alternately to the left GDM unit 114 and to the right GDM unit 114. In the present embodiment, the gate drive circuit is provided not in the gate drivers 14 in accordance with Embodiment 1, but in the GDM units 114. Therefore, unlike Embodiment 1, the present embodiment includes no gate inspection lines 65, no gate inspection TFTs 61, no gate-inspection-TFT control line 63, no gate-inspection-TFT pull-out lines 62, and no dummy line 72.

Each source line 143 has a lower end portion 143E1 thereof connected to a drain electrode 151D of an associated one of the source inspection TFTs 151 as shown in FIGS. 11 and 12. The lower end portion 143E1 has a branching terminal 143E1A formed on the display area AA side of the connecting site for the drain electrode 151D. The branching terminal 143E1A is a terminal to which the source driver 112 and the source lines 143 are connected. The source lines 143 are fed with data signals from the source driver 112 via the branching terminals 143E1A when the liquid crystal panel 110 is driven. Meanwhile, when the array substrate 130 (liquid crystal panel 110) is subjected to an operation test, the source lines 143 are fed with data inspection signals from an external inspection instrument via the source inspection lines 155, the source-inspection pull-out lines 152, and the source inspection TFTs 151 in this order.

At least two (six in the present embodiment) source inspection lines 155 are provided parallel to each other as shown in FIGS. 11 and 12. One of the six source inspection lines 155 that is the closest to the non-display area NAA (source inspection line 155A, which is the first source inspection line 155 when counted along the Y-axis direction from the top of FIG. 11) is connected via the source-inspection pull-out lines 152 to those source inspection TFTs 151 that are the first, seventh, thirteenth, . . . when counted from the left side of FIG. 11. Meanwhile, one of the source inspection lines 155 that is immediately below the source inspection line 155A (source inspection line 155B, which is the second source inspection line 155 when counted along the Y-axis direction from the top of FIG. 11) is connected via the source-inspection pull-out lines 152 to those source inspection TFTs 151 that are the second, eighth, fourteenth . . . when counted from the left side of FIG. 11. Likewise, those source inspection lines 155 that are the third, fourth, fifth, and sixth when counted along the Y-axis direction from the top of FIG. 12 (source inspection lines 155C, 155D, 155E, and 155F) are connected respectively to the source inspection TFTs 151 via the source-inspection pull-out lines 152.

### Embodiment 3

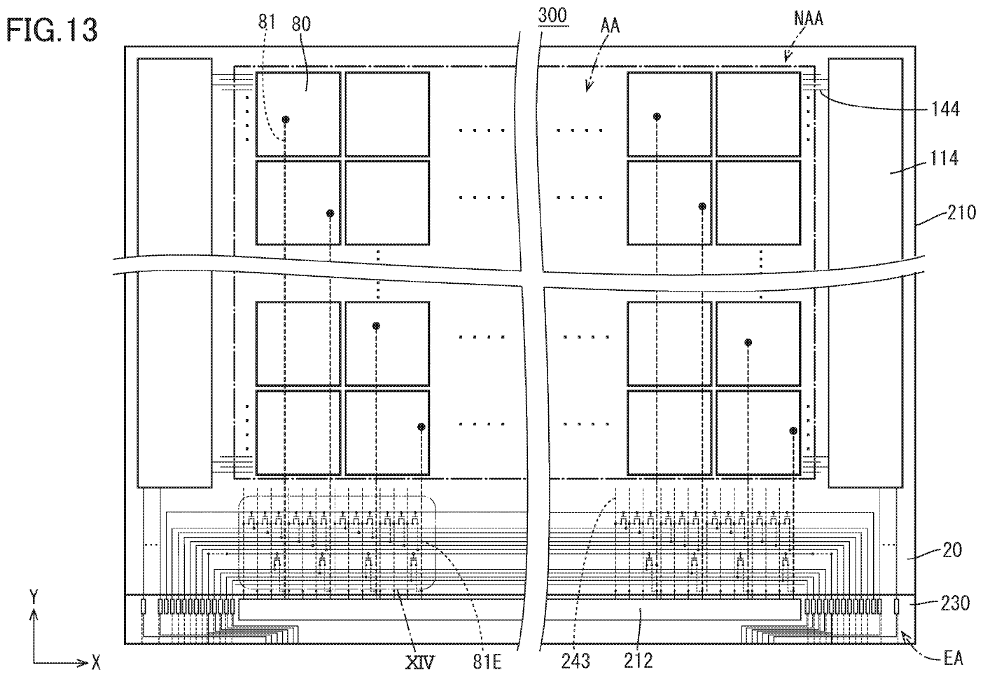

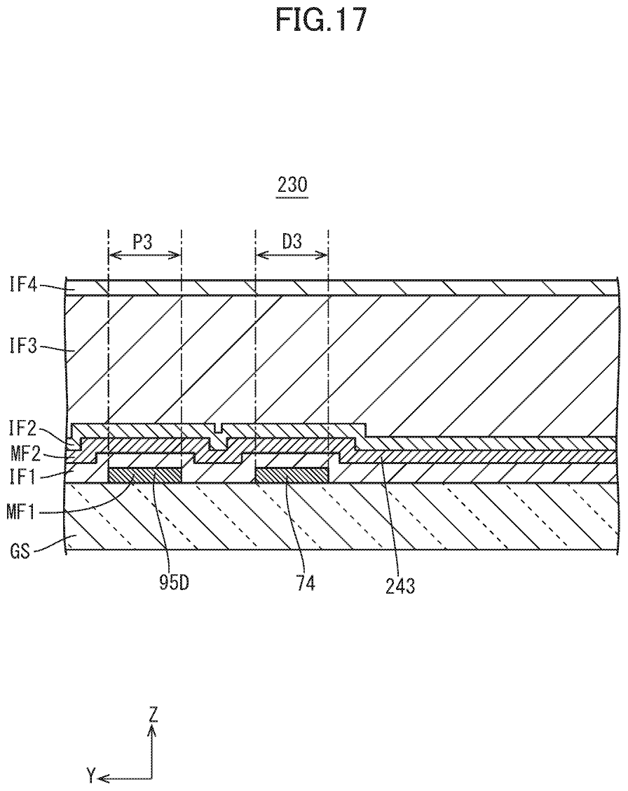

The following will describe a liquid crystal display device 300 in accordance with Embodiment 3 with reference to FIGS. 13 to 17. Duplicate description is omitted of the structures, operations, effects, and advantages of Embodiment 3 that are similar to those of Embodiments 1 and 2.

A liquid crystal panel 210 in accordance with the present embodiment has a touch panel function of detecting a user input location on the basis of an image display as well as a display function of displaying images. A touch panel pattern is formed integrally to various thin films 230A on an array substrate 230 to implement the touch panel function (in-cell structure). The touch panel pattern is composed of a matrix of touch electrodes 80 in a display area AA on the array substrate 230 as shown in FIG. 13. As the user moves a finger (position input body, which is an electrical conductor) close to the surface (display surface) of the liquid crystal panel 210 to make a position-dependent input on the basis of a visible image displayed in the display area AA of the liquid crystal panel 210, there is formed electrostatic capacitance between the finger and the touch electrodes 80. In this structure, when the finger approaches, the electrostatic capacitance detected by the touch electrodes 80 that are close to the finger changes, deviating from the electrostatic capacitance detected by the touch electrodes 80 that are far from the finger. It is thus possible to detect the input location from these changes. The touch electrodes 80 have far larger dimensions than the pixel electrodes 47 in a plan view and are formed by dividing the common electrode 48 by partition openings.

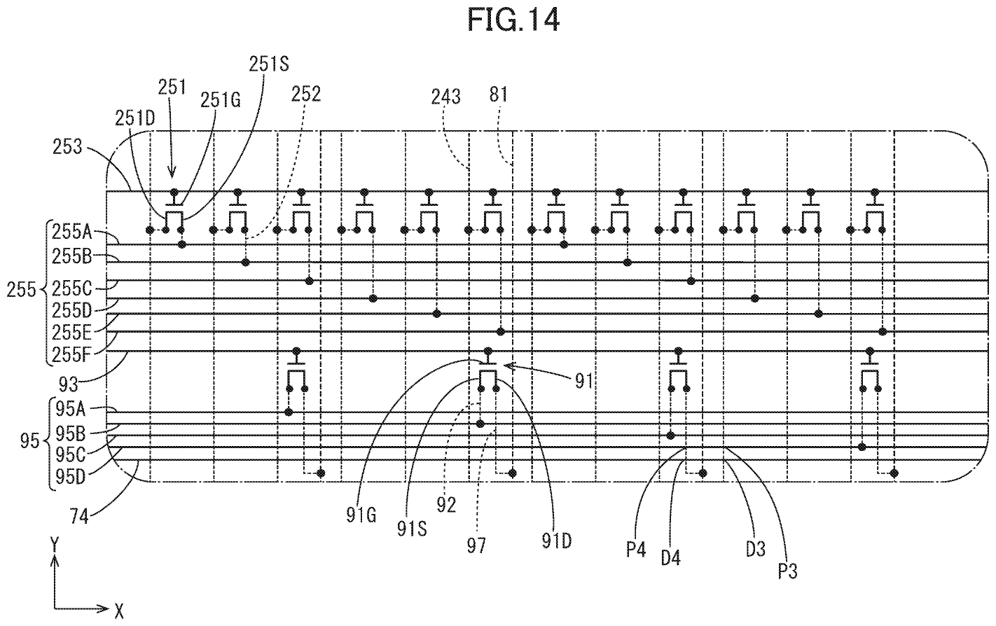

The touch electrodes 80 are connected to touch lines 81 (another example of the first lines) on the array substrate 230 as shown in FIG. 13. The touch lines 81 are extended generally in the Y-axis direction and selectively connected to specific touch electrodes 80. At least two touch lines 81 are formed at such intervals that two of the touch lines 81 run parallel to six source lines 243 as shown in FIG. 14. The touch lines 81 have lower end portions 81E1 thereof connected to a location detection circuit in a source driver 212. The touch lines 81 supply reference electrical potential signals related to the display function and touch signals (location detection signals) related to the touch function to the touch electrodes 80 at different timings. The reference electrical potential signals are fed to all the touch lines 81 at the same timing, thereby placing all the touch electrodes 80 at the reference electrical potential so that the touch electrodes 80 can serve as the common electrode 48. FIG. 13 omits the source lines 243 and the gate lines 144 in the display area AA to distinctly show the touch electrodes 80 and the touch lines 81.

The array substrate 230 includes source inspection lines 255, source-inspection switching elements 251, a source-inspection-TFT control line 253, and source-inspection-TFT pull-out lines 252 to supply data inspection signals to the source lines 243 as shown in FIG. 14. These wiring and TFTs have the same basic configuration as the source inspection lines 155, the source-inspection switching elements 151, the source-inspection-TFT control line 153, and the source-inspection pull-out lines 152 of Embodiment 2. Unlike Embodiment 2, however, the wiring and TFTs are located in the non-display area NAA between the display area AA and the source driver 212, not within an area for mounting the source driver 212. In addition, unlike Embodiments 1 and 2, no dummy line is provided immediately next to a source inspection line 255F.

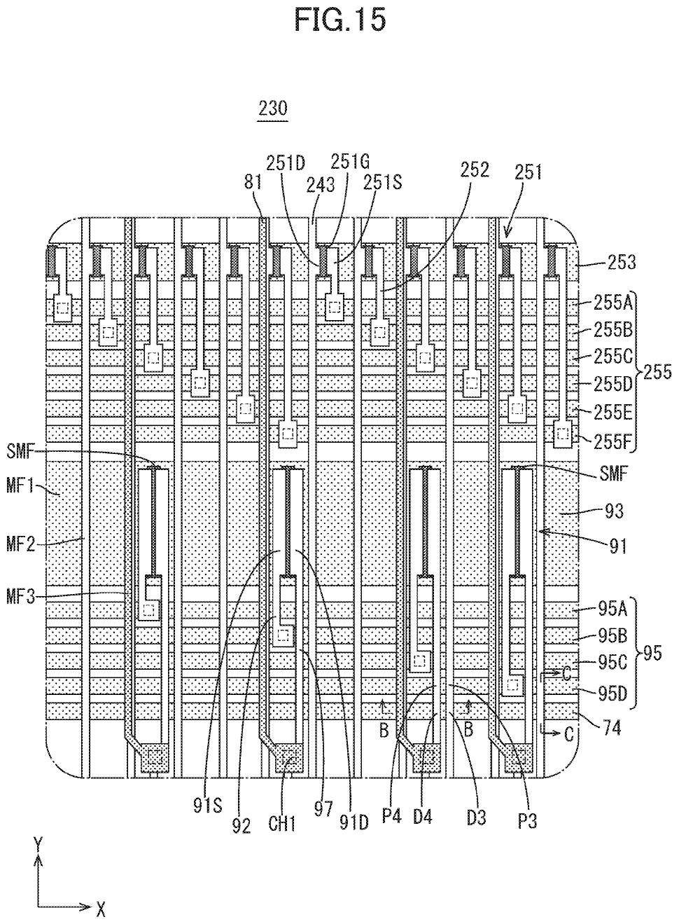

The array substrate 230 includes touch inspection lines 95, touch inspection TFTs 91, a touch-inspection-TFT control line 93, first touch-inspection-TFT pull-out lines 92, and second touch-inspection-TFT pull-out lines 97 to supply inspection touch signals (touch inspection signals) to the touch lines 81 as shown in FIGS. 14 and 15. These wiring and TFTs for supplying touch inspection signals are disposed closer to the outer peripheral portion of the non-display area NAA than the wiring and TFTs for supplying the source signals (the source inspection lines 255, the source-inspection switching elements 251, the source-inspection-TFT control line 253, and the source-inspection-TFT pull-out lines 252) are close to the outer peripheral portion of the non-display area NAA. The touch inspection lines 95 are fed with touch inspection signals from an external inspection instrument. The touch inspection TFTs 91 control the feeding of the data inspection signals from the touch inspection lines 95 to the touch lines 81. The touch-inspection-TFT control line 93 is fed with a switching signal for switching the driving of the touch inspection TFTs 91. The first touch-inspection-TFT pull-out lines 92 are pulled out in the Y-axis direction so as to connect the touch inspection lines 95 to source electrodes 91S of the touch inspection TFTs 91. The second touch-inspection-TFT pull-out lines 97 are pulled out in the Y-axis direction so as to connect the touch lines 81 to drain electrodes 91D of the touch inspection TFTs 91.

There is provided one touch inspection TFT 91 for each touch line 81 as shown in FIGS. 14 and 15. At least two (four in the present embodiment) touch inspection lines 95 are provided parallel to each other. One of the four touch inspection lines 95 that is the closest to the display area NAA (touch inspection line 95A, which is the first touch inspection line 95 when counted along the Y-axis direction from the top of FIG. 14) is connected via the first touch-inspection-TFT pull-out lines 92 to those touch inspection TFTs 91 that are the first, fifth, ninth . . . when counted from the left side of FIG. 14. Meanwhile, one of the four touch inspection lines 95 that is immediately below the touch inspection line 95A (touch inspection line 95B, which is the second touch inspection line 95 when counted along the Y-axis direction from the top of FIG. 14) is connected via the first touch-inspection-TFT pull-out lines 92 to those touch inspection TFTs 91 that are second, sixth, tenth . . . when counted from the left side of FIG. 14. Likewise, those touch inspection lines 95 that are the third and fourth when counted along the Y-axis direction from the top of FIG. 14 (touch inspection lines 95C and 95D) are connected respectively to the touch inspection TFTs 91 via the first touch-inspection-TFT pull-out lines 92.

The array substrate 230 includes a dummy line 74 as an ESD countermeasure that may occur on the touch inspection lines 95 as shown in FIGS. 14 and 15. In the present embodiment, the touch inspection lines 95 are located close to the outer peripheral portion of the non-display area NAA and therefore likely to provide paths for ESD occurrences. Accordingly, the dummy line 74 is provided closer to the outer peripheral portion than all the four touch inspection lines 95 are close to the outer peripheral portion. The dummy line is extended generally straightly in the X-axis direction and is located adjacent to the touch inspection line 95D, which is one of the four touch inspection lines 95 that is the closest to the outer peripheral portion of the non-display area NAA.

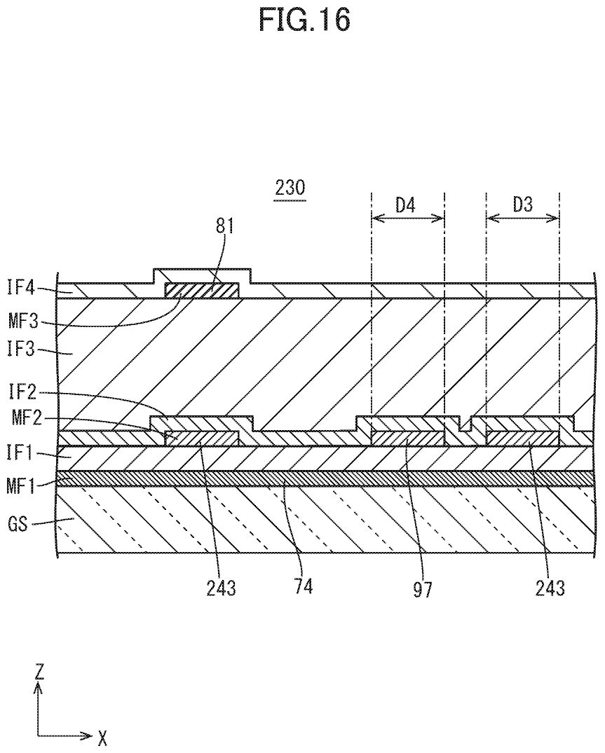

In the various thin films 230A on the array substrate 230, gate electrodes 91G of the touch inspection TFTs 91, the touch-inspection-TFT control line 93, the touch inspection lines 95, and the dummy line 74 are formed by patterning the gate metal film MF1 as shown in FIGS. 15 to 17. The source electrodes 91S and the drain electrodes 91D of the touch inspection TFTs 91 and the touch-inspection-TFT pull-out lines 92 and 97 are formed by patterning the source metal film MF2. The touch inspection TFTs 91 are bottom-gate TFTs. A semiconductor film SMF, which will be channel regions for the TFTs, is stacked between the gate insulation film IF1 and the source metal film MF2 in the area where these TFTs are provided. The touch lines 81 are formed by patterning a touch metal film MF3 (an example of the third metal film) on the first interlayer insulation film IF2 and the planarization film IF3 (an example of the second insulation film) disposed on an overlying side of the source metal film MF2. A second interlayer insulation film (passivation film, inorganic insulation film) IF4 is stacked on the touch metal film MF3 as shown in FIG. 16. The touch metal film MF3 is made of either a monolayer film of a metal such as copper (Cu) or of an alloy or a stack of these films, so that every wire and electrode made from the metal film MF3 is electrically conductive and opaque to light. The touch metal film MF3 may be made of the same material as, or a different material from, the gate metal film MF1 and the source metal film MF2. The second transparent electrode film, from which the touch electrodes 80 and the common electrode 48 are made, is disposed on the second interlayer insulation film IF4 in the display area AA.

The source lines 243 are passed on the overlying side of the touch inspection lines 95 and the dummy line 74 and extended toward the outer peripheral portion of the non-display area NAA, as shown in FIGS. 14 and 15. The touch lines 81, made from the touch metal film MF3, form interlayer connections via contact holes CH1 to the second touch-inspection-TFT pull-out lines 97 made from the source metal film MF2 as shown in FIG. 15. The contact holes CH1 are disposed closer to the outer peripheral portion of the non-display area NAA than the dummy line 74 is close to the outer peripheral portion of the non-display area NAA. Therefore, if there was provided no dummy line 74, the intersecting sites P3 and P4 on the touch inspection line 95D made from the gate metal film MF1, the source lines 243 made from the source metal film MF2, and the second touch-inspection-TFT pull-out lines 97 would be ESD-prone sites that will likely to provide paths for ESD and cause ESD-induced interlayer leak current on the array substrate 230.

Accordingly, in the present embodiment, by providing the dummy line 74, overlapping sites D3 and D4 where the gate metal film MF1 intersects with (overlaps) the source metal film MF2 are formed closer to the outer peripheral portion of the non-display area NAA than the ESD-prone sites P3 and P4 are close to the outer peripheral portion of the non-display area NAA. In this particular structure, the overlapping sites D3 and D4 can behave like a lightning rod to ESD, thereby restraining an ESD-induced leak current from occurring at the ESD-prone sites P3 and P4.

### OTHER EMBODIMENTS

The present invention is not necessarily limited to the description and embodiments detailed above with reference to drawings. The scope of the present invention encompasses, for example, the following embodiments.

(1) The dummy lines 70, 72, 74, and 170 may not have the same width and shape as those portions adjacent to the inspection lines 55B, 65A, 155F, and 95D.

(2) The order in which various thin films are stacked on the array substrates 30, 130, and 230 is a mere example. As an alternative example, the gate metal film MF1 may be overlying the source metal film MF2 with an insulation film interposed therebetween.

(3) The various wires and lines shown in drawings may be varied in the number, locations, and planar shape thereof.

(4) The liquid crystal panels 10, 110, and 210 may be driven by multi pixel drive whereby the colored film of each color is further divided in each pixel in controlling the gray level thereof.

(5) On the CF substrate 20, the colored films may be arranged in such a manner that the colors repeatedly appear in a prescribed sequence when traced along the X-axis direction. The colored films may have any color other than red, green, and blue and may have less than or more than three colors. No color filters may be provided, in which case the display panel produces monochromic images.

(6) The array substrates 30, 130, and 230, the liquid crystal panels 10, 110, and 210, the liquid crystal display devices 100, 200, and 300 may have any shape other than landscape-oriented rectangular.

(7) The embodiments above discussed liquid crystal panels as an example of the display panel. The subject technology is alternatively applicable to other types of display panels such as OLED (organic light-emitting diode) panels. The OLED panel 410 includes at least an array substrate 430, an organic light-emitting layer (light-emitting elements) 418 on the array substrate 430, and a sealing layer 440 provided so as to cover the light-emitting elements 418, as shown in FIG. 18.

What is claimed is:

1. An array substrate having a display area and a non-display area surrounding the display area, the array substrate comprising:
a plurality of first lines running in parallel in a first direction in the display area;
a plurality of second lines running in parallel in a second direction in the display area, the second direction intersecting with the first direction;
an inspection switching element in the non-display area, the inspection switching element being connected to the plurality of first lines extended from the display area;
a plurality of third lines running in the first direction in the non-display area, the plurality of third lines being connected to either a source electrode or a drain electrode of the inspection switching element;
a plurality of inspection lines running in the second direction in the non-display area, the plurality of inspection lines being connected respectively to the plurality of third lines; and
a dummy line running in the second direction in the non-display area, the dummy line being adjacent to an outermost inspection line that is one of the plurality of inspection lines that is located closest to an outer peripheral portion of the non-display area, wherein
at least one of the plurality of inspection lines and the dummy line overlap the plurality of third lines with a first insulation film intervening therebetween in such a manner as to intersect with the plurality of third lines in a plan view, and
overlapping regions where the dummy line overlaps the plurality of third lines are closer to the outer peripheral portion of the non-display area than are overlapping regions where the plurality of inspection lines overlap the plurality of third lines.

2. The array substrate according to claim 1, wherein the dummy line is closer to the outer peripheral portion of the non-display area than is the outermost inspection line.

3. The array substrate according to claim 1, wherein
the first insulation film is destructed in the overlapping regions where the dummy line overlaps the plurality of third lines, so that the dummy line is short-circuited to the plurality of third lines at a short-circuiting site, and
the dummy line is partially cut such that the short-circuiting site is electrically isolated on the plurality of third lines.

4. The array substrate according to claim 1, wherein
the plurality of first lines are source lines connected to source electrodes of pixel switching elements arranged in a matrix in the display area,
the plurality of second lines are gate lines connected to gate electrodes of the pixel switching elements, and
the gate lines, the plurality of inspection lines, and the dummy line are made from a first metal film, and the source lines and the plurality of third lines are made from a second metal film disposed in an overlying layer of the first metal film with the first insulation film intervening therebetween.

5. The array substrate according to claim 1, wherein
the plurality of first lines are gate lines connected to gate electrodes of pixel switching elements arranged in a matrix in the display area,
the plurality of second lines are source lines connected to source electrodes of the pixel switching elements, and
the gate lines, the plurality of inspection lines, and the dummy line are made from a first metal film, and the source lines and the plurality of third lines are made from a second metal film disposed in an overlying layer of the first metal film with the first insulation film intervening therebetween.

6. The array substrate according to claim 1, further comprising a matrix of touch electrodes in the display area, the touch electrodes being configured to form electrostatic capacitance between the touch electrodes and a position input body for use in making a position-dependent input and to detect a location of an input made using the position input body, wherein
the plurality of first lines are touch lines connected to the touch electrodes,
the plurality of second lines are gate lines connected to gate electrodes of pixel switching elements arranged in a matrix in the display area, and
the gate lines, the plurality of inspection lines, and the dummy line are made from a first metal film, the plurality of third lines are made from a second metal film disposed in an overlying layer of the first metal film with the first insulation film intervening therebetween, and the touch lines are made from a third metal film disposed in an overlying layer of the second metal film with a second insulation film intervening therebetween.

7. A display panel comprising:
the array substrate according to claim 1;
an opposite substrate disposed facing the array substrate in such a manner as to have an internal space between the opposite substrate and the array substrate; and
a medium layer of functional organic molecules in the internal space.

8. A display panel comprising:
the array substrate according to claim 1;
light-emitting elements on the array substrate; and
a sealing layer disposed so as to cover the light-emitting elements.

9. A display device comprising the display panel according to claim 7.
